(19) United States
(12) Patent Application Publication
(10) Pub. No.: US 2013/0249571 A1
(43) Pub. Date: Sep. 26, 2013

(54) TOUCH PANEL SENSOR

(71) Applicants: Hiroyuki Okuno, Kobe-shi (JP); Aya Miki, Kobe-shi (JP); Toshihiro Kugimiya, Kobe-shi (JP)

(72) Inventors: Hiroyuki Okuno, Kobe-shi (JP); Aya Miki, Kobe-shi (JP); Toshihiro Kugimiya, Kobe-shi (JP)

(73) Assignee: Kabushiki Kaisha Kobe Seiko Sho (Kobe Steel, Ltd.), Kobe-shi, Hyogo (JP)

(21) Appl. No.: 13/990,981

(22) PCT Filed: Nov. 30, 2011
(86) PCT No.: PCT/JP2011/077701

§ 371 Date: May 31, 2013

(30) Foreign Application Priority Data
Dec. 1, 2010 (JP) 2010-268687
Dec. 1, 2010 (JP) 2010-268688
Dec. 1, 2010 (JP) 2010-268689

(51) Int. Cl. G01R 1/04

(52) U.S. Cl. CPC G01R 1/04
USPC 324/691

(57) ABSTRACT

Provided is a touch panel sensor which has excellent durability particularly in a longitudinal direction as in the case in which an indentation load is imposed, rarely undergoes the increase in electrical resistivity which may be caused by the disconnection of a wire or as elapse of time, has high reliability and high glossiness, and also has an excellent color-displaying capability. This touch panel sensor comprises a transparent conductive film and a wiring that is connected to the transparent conductive film, wherein the wiring comprises a refractory metal film, an Al alloy film and a high-melting-point metal film in this order when observed from the side of a substrate, and wherein the Al alloy film contains a rare earth element in an amount of 0.05-5 atomic %. It is preferred for the touch panel sensor that the hardness is 2-3.5 GPa and the density of grain boundary triple junctions in the Al alloy structure is 2×10⁸ /mm² or more. It is also preferred for the touch panel sensor that the Young's modulus is 80-200 GPa and the maximum value of the unidirectional tangential diameter (Feret diameter) of grain boundary is 100-350 nm. It is also preferred for the touch panel sensor that the glossiness is 800% or higher.

### TECHNICAL FIELD

The present invention relates to a touch panel sensor having a transparent conductive film and a wiring connected to this film.

### BACKGROUND ART

Touch panel sensors disposed on the front side of an image display device and used as an input switch integral with the image display device are easy to use, and thus have been widely used in operation screens of, for example, an automated teller machine of a bank, a ticket-vending machine, a car navigation system, a PDA, a copy machine, and the like. Detection mechanisms of an input point include a resistance film type, a capacitance type, an optical type, an ultrasonic surface elastic wave type, a piezoelectric type, and the like. Among them, the resistance film type detection mechanism is most widely used because of low cost, simple structure, and the like.

The resistance film type touch panel sensor mainly includes an upper electrode, a lower electrode, and a tail. A transparent conductive film provided on a substrate (for example, a film substrate) included in the upper electrode, and a transparent conductive film provided on another substrate (for example, a glass substrate) included in the lower electrode are opposed to each other via a spacer. When a finger, a pen, or the like touches the film side of such a touch panel sensor, both transparent conductive films are brought into contact with each other, so that current flows through the electrodes on both ends of the transparent conductive films. And, a voltage division ratio due to resistances of the respective transparent conductive films is measured thereby to detect the touched position.

In a process for manufacturing a touch panel sensor, a guiding wiring for coupling the transparent conductive film to a control circuit or a wiring for connecting the transparent conductive films, such as a metal wiring, is generally formed by printing a conductive paste, such as a silver paste, or a conductive ink by ink-jet technology or other printing methods. The wiring made of pure silver or silver alloy, however, has bad adhesion to glass, resin, or the like. Further, the wiring material is flocculated on the substrate at a contacting part to an external device, which leads to an increase in electrical resistance or failures, such as disconnection.

The touch panel sensor is a sensor for sensing the presence of touch of a finger of a person or the like. The touch panel sensor is temporarily deformed slightly due to a stress applied by the touch. The repeated use of the touch panel repeatedly causes the slight deformation, so that the stress is also repeatedly applied to the wiring. Thus, the wiring is required to have adequate durability (resistance to stress). The wiring formed using the conductive paste made of pure silver or silver alloy does not have enough durability. The wiring may be easily damaged during using the touch panel. The damage to the wiring increases the electrical resistance of the wiring to induce a voltage drop, which tends to reduce the accuracy of detecting the position by the touch panel sensor. In employing a pen touch type touch panel, it is necessary to narrow a pitch between the wirings. However, the formation of the wiring using the paste is performed by a coating technique, which makes it difficult to narrow the pitch.

On the other hand, it is also proposed that pure aluminum having a sufficient low electrical resistivity is applied as material of the wiring. The use of pure aluminum as material for the wiring, however, forms insulating aluminum oxide between the pure aluminum film and the transparent conductive film in the touch panel sensor, which cannot ensure the electrical conductivity. To this end, there have been suggested a method including interposing a barrier metal layer consisting of a refractory metal such as Mo and Ti between a transparent conductive film and a pure Al film and used as an underlayer to ensure electrical conductivity by preventing oxidation of Al, and a method including using an Al-Nd alloy containing Nd having good heat resistance and other properties in place of pure Al. Moreover, the applicant of the present application discloses in patent document 1 an Al-Ni/Co alloy film (single-layer wiring material) containing a predetermined amount of Ni and/or Co as an Al film which shows low electrical resistivity even when it is brought into direct contact with a transparent conductive film, while it is unlikely to involve an increase in electrical resistivity over time or disconnection.

### PRIOR ART DOCUMENT

### Patent Document

Patent document 1; Japanese Unexamined Patent Publication No. 2009-245422

### SUMMARY OF THE INVENTION

### Problems to be Solved by the Invention

An object of the present invention is to provide a touch panel sensor with high reliability, high glossiness, and excellent color expression which is excellent in durability in the lateral direction such as push load, and is less likely to cause disconnection or an increase in electrical resistance with the elapse of time.

### Means for Solving the Problem

The present invention provides the touch panel sensor described below.
(1) In a touch panel sensor having a transparent conductive film, and a wiring which is connected with the transparent conductive film, the wiring includes, in the order from the substrate side, a refractory metal film, an aluminum alloy film, and a refractory metal film, and the aluminum alloy film contains a rare-earth element in an amount of 0.05 to 5 atomic %.
(2) A touch panel sensor according to (1), wherein the rare-earth element is one or more element selected from the group consisting of Nd, Gd, La, Y, Ce, Pr and Dy.
(3) A touch panel sensor according to (1) or (2), wherein the transparent conductive film includes indium tin oxide (ITO) or indium zinc oxide (IZO).
(4) A touch panel sensor according to any one of (1) to (3), wherein the aluminum alloy film contains a rare-earth element in an amount of 0.05 to 1 atomic %; has hardness of 2 to 3.5 GPa; and has a density of grain boundary triple junction present in an Al alloy structure of 2×10⁸/mm² or higher.
(5) A touch panel sensor according to any one of (1) to (4), wherein the Young's modulus of the Aluminum alloy film is 80 to 200 GPa, and the maximum value of the unidirectional tangential diameter (Feret diameter) of crystal grains is 100 to 350 nm.
(6) A touch panel sensor according to any one of (1) to (5), wherein the glossiness of the aluminum alloy film is 800% or higher.

### Effect of the Invention

According to the present invention, in a touch panel sensor using a wiring material in which refractory metal films are disposed above and below an aluminum alloy film containing a rare-earth element as a wiring for a touch panel sensor, the hardness and grain boundary triple junction density of the above aluminum alloy film are appropriately controlled, and therefore a touch panel sensor with high reliability which has excellent durability, in particular, in the vertical direction such as push load, and hardly causes disconnection or an increase in electrical resistance with the elapse of time could be provided. The present invention is effective as various kinds of touch panels, and is suitably used for a contact-type touch panel sensor operated by pressing portions displayed on the screen, for example, automatic teller machines installed in financial institutions such as banks, and automatic vending machines at stations and restaurants. Moreover, since the Young's modulus and the maximum value of the unidirectional tangential diameter of crystal grains (Feret diameter) of the above aluminum alloy film are appropriately controlled, a touch panel sensor with high reliability which has excellent durability in the lateral direction in particular, and hardly causes disconnection or an increase in electrical resistivity with the elapse of time could be provided. The touch panel of the present invention is suitably used for a capacitative touch panel sensor, for example, a portable game console and a tablet type computer, which is operated by sliding a finger or the like on a screen thereof in many directions. Furthermore, use of an aluminum alloy film having excellent glossiness allows providing a touch panel sensor with excellent color expression.

### Mode for Carrying out the Invention

The inventors of the present invention have made an extensive examination to provide a wiring material having the above-mentioned features and effects in a touch panel sensor having a wiring material widely used as a wiring for a touch panel sensor, that is, a wiring material in which refractory metal films of Mo or the like are laminated above and below an aluminum alloy film containing a rare-earth element (hereinafter referred to as Al-rare-earth element alloy film, or may be simply abbreviated as aluminum alloy film.). As a result, the inventors have found that as the above Al-rare-earth element alloy film, the use of an aluminum alloy film having predetermined hardness and grain boundary density, or an aluminum alloy film having a Young's modulus and the maximum value (hereinafter sometimes abbreviated as maximum grain size.) and a unidirectional tangential diameter (Feret diameter) of crystal grains, or an aluminum alloy film having a glossiness of 800% or higher achieves desired objects, and have completed the present invention.

That is, a feature of the present invention lies in employing, as an Al-rare-earth alloy film for a wiring used with a refractory metal film, an aluminum alloy film having hardness of 2 to 3.5 GPa, and a density of grain boundary triple junction existing in an Al alloy structure of 2×10⁸/mm² or higher, or an aluminum alloy film having a Young's modulus of 80 to 200 GPa and the maximum value of the unidirectional tangential diameter (Feret diameter) of crystal grains (hereinafter sometimes abbreviated as maximum grain size.) of 100 to 350 nm, or an aluminum alloy film having a glossiness of 800% or higher.

The aluminum alloy film for use in the present invention contains a rare-earth element in an amount of 0.05 to 5 atomic %. It is preferable that the remainder is Al and inevitable impurities. In the present invention, the composition of the aluminum alloy film used has no feature. Although it is known that an aluminum alloy film containing a rare-earth element has heat resistance and is used as a wiring material, an aluminum alloy film having controlled hardness and triple junction density, an aluminum alloy film having controlled Young's modulus and the maximum grain size, or an aluminum alloy film having appropriately controlled glossiness and the amount of rare-earth elements contained from the perspective of providing a material suitable especially for a contact-type touch panel sensor has not been disclosed yet.

First, it is preferable that the hardness of the Al-rare-earth alloy film is 2 to 3.5 GPa. Touch panels are required to have excellent deformability (followability) when touched (during use), and have durability in the vertical direction to such a degree that prevents occurrence of disconnection, rupture, peeling or other problem of the wiring especially when the screen is strongly touched with a pen, a finger or the like so that an excessive load is imposed, and stress is temporarily concentrated at the end of the sensor and the wiring is deformed and deteriorated. The above hardness has been set from such a perspective, and has been also set in consideration of the balance for the hardness of the refractory metal films disposed above and below the aluminum alloy film.

Described in more detail, when the wiring material forming the wiring is too soft, deformation of the wiring due to stress concentration is repeated to deteriorate the wiring, and rupture, peeling or other problems may occur to disadvantageously increase electrical resistivity in some cases. In contrast, when the wiring material is too hard, deformation due to push load is unlikely to occur, and therefore fine cracks may be produced and deterioration such as peeling may occur. Moreover, when a laminate including an aluminum alloy film and refractory metal films is used as a wiring material as in the present invention, in setting the hardness of the aluminum alloy film, the balance with the hardness of the refractory metal films needs to be further considered. The upper limit of the hardness of the aluminum alloy film is preferably controlled to be approximately similar to the hardness of the refractory metal constituting the refractory metal films. In contrast, the lower limit of the hardness of the aluminum alloy film is preferably not very different from the hardness of the refractory metal. From such a perspective, in the present invention, the hardness of the aluminum alloy film is defined to be 2 GPa or higher but 3.5 GPa or lower. It is preferably 2.5 GPa or higher but 3.3 GPa or lower. It should be noted that the hardness of the aluminum alloy film is a value which is measured by the method described in Examples described later.

Furthermore, the aluminum alloy film for use in the present invention is such that its density of grain boundary triple junction existing in the Al alloy structure (hereinafter may be abbreviated as triple junction density.) satisfies 2×10⁸/mm² or higher. As described above, in the present invention, the hardness of the aluminum alloy film needs to be controlled to fall within a predetermined range, but normally, hardness is in close relationship with the triple junction density, and when the amount of the rare-earth element contained is within the range of the present invention (1 atomic % or lower), the greater the triple junction density is, the greater the hardness. In the present invention, from the perspective of ensuring the lower limit of the hardness of the aluminum alloy film (2 GPa), the triple junction density is defined to be 2×10⁸/mm² or higher. It is preferably 2.4×10⁸/mm² or higher. The upper limit of the triple junction density, considering the efficiency of sputtering film formation and the like, is preferably 8.0×10⁸/mm². It should be noted that the triple junction density of the aluminum alloy film is a value which is measured by the method described in Examples described later.

The aluminum alloy film for use in the present invention, from the perspective of ensuring the ranges of the above hardness and triple junction density, preferably contains a rare-earth element in an amount of 0.05 to 1 atomic %, with the remainder being Al and inevitable impurities. As shown in Examples described later, the hardness tends to be lowered as the amount of the rare-earth element is lowered, and in the aluminum alloy film having the amount of the rare-earth element contained lower than the lower limit defined in the present invention, at least one of the hardness or triple junction density falls outside the range of the present invention. In contrast, as the amount of the rare-earth element contained increases, the hardness tends to increase, and in the aluminum alloy film having the amount of the rare-earth element contained higher than the above upper limit, at least one of the hardness or triple junction density falls outside the range of the present invention.

The Young's modulus of the Al-rare-earth alloy film is preferably set to 80 to 200 GPa. When the Young's modulus of the wiring material constituting the wiring is small (too soft), deformation of the wiring due to stress concentration is repeated to deteriorate the wiring, and rupture, peeling or other problems may occur to disadvantageously increase electrical resistivity in some cases. In contrast, if the Young's modulus of the wiring material is high (too hard), deformation due to push load is unlikely to occur, and therefore fine cracks may be produced and deterioration such as peeling may occur. Moreover, when a laminate including the aluminum alloy film and refractory metal films is used as a wiring material as in the present invention, in setting the Young's modulus of the aluminum alloy Mm, the balance with the Young's modulus of the refractory metal film needs to be further considered, and the upper limit of the Young's modulus of the aluminum alloy film is preferably controlled to be approximately similar to the Young's modulus of the refractory metal constituting the refractory metal films. In contrast, the lower limit of the Young's modulus of the aluminum alloy film is preferably not very different from the Young's modulus of substrates typically including glass substrate. From such a perspective, in the present invention, the Young's modulus of the aluminum alloy film is defined to be 80 GPa or higher but 200 GPa or lower. It is preferably 85 GPa or higher but 180 GPa or lower. It should be noted that the Young's modulus of the aluminum alloy film is a value which is measured by the method in Example described later.

Furthermore, the maximum grain size [the maximum value of the unidirectional tangential diameter (Feret diameter) of crystal grains] of the aluminum alloy film used in the present invention preferably falls within the range from 100 to 350 nm. As described above, in the present invention, the Young's modulus of the aluminum alloy film needs to be controlled to fall within a predetermined range, but normally, the Young's modulus is generally in close relationship with the maximum grain size. When the amount of the rare-earth element contained is within the range of the present invention (5 atomic % or lower), the Young's modulus tends to decrease as the maximum grain size increases. In the present invention, from the perspective of ensuring the lower limit (80 GPa) of the Young's modulus of the aluminum alloy film, the upper limit of the maximum grain size is defined to be 350 nm, and from the perspective of ensuring the upper limit (200 GPa) of the Young's modulus of the aluminum alloy film, the lower limit of the maximum grain size is defined to be 100 nm. A preferable maximum grain size is 130 nm or greater but 320 nm or smaller.

Herein, the maximum grain size means the maximum value of the unidirectional tangential diameter of crystal grains (also referred to as Feret diameter or Green diameter). Specifically, it is the interval (distance) between two parallel lines nipping a particle extending in a constant direction, and when a crystal grain has a recess, it is the distance between parallel outer tangential lines in the projection drawing, while when the crystal grain has no recess (sphere), it is a value obtained by dividing the circumference by π.

The aluminum alloy film for use in the present invention, as described above, contains a rare-earth element in an amount of 0.05 to 5 atomic % (the remainder is preferably Al and inevitable impurities). By setting the amount of the rare-earth element contained to the above lower limit or higher, heat resistance effects can be effectively produced, while in contrast, by setting the amount to the above upper limit or lower, the ranges of the Young's modulus and maximum grain size defined in the present invention can be ensured. As the amount of the rare-earth element contained increases, the Young's modulus tends to increase and the maximum grain size tends to decrease.

The inventors have found the followings:
(I) the glossiness of a wiring film has great influence on the tone of the touch panel sensor, and when the grain size (in detail the maximum value of the unidirectional tangential diameter referred to as the Feret diameter) of crystal grains of the aluminum alloy film mentioned above constituting the wiring material is large, or when the density of the grain size is small, the glossiness of the aluminum alloy film is reduced, resulting in lower color expression of the touch panel sensor, (II) described in detail, the glossiness of the aluminum alloy film is determined mostly by the above grain size and density immediately after the formation of the film, and almost no change in glossiness is found even when a heat treatment (annealing) is performed after the film formation, (III) in order to achieve high glossiness, appropriately controlling film formation conditions (preferably, the temperature and Ar gas pressure during sputtering) is effective. Furthermore, the amount of the rare-earth element contained in the aluminum alloy film also has a close relationship with the glossiness of the aluminum alloy film, and the inventors have also found: (IV) glossiness tends to increase as the amount of the rare-earth element contained increases, adding the rare-earth element in a large amount impairs the tone of the touch panel sensor due to the problem of etching residues, and therefore controlling its upper limit to 5 atomic % is effective; and (V) thus, the aluminum alloy film having the amount of the rare-earth element contained and glossiness have been appropriately controlled can be used singly as a material of a wiring for a touch panel sensor, or can be used as a laminate material on which a refractory metal film such as Mo is laminated, completing the present invention.

The glossiness of the Al-rare-earth alloy film is preferably set to 800% or higher. This also increases the glossiness of the touch panel sensor. The higher the glossiness, the better, and it is preferably 805% or higher. It should be noted that the upper limit of the glossiness of the aluminum alloy film is not particularly defined, but considering the conditions for ensuring desired glossiness (the amount of the rare-earth element contained in the aluminum alloy film and production conditions of the aluminum alloy film, etc., will be described later in detail.), it is about 840%. The glossiness of the aluminum alloy film is a value measured by the method which is described in Examples described later.

The aluminum alloy film for use in the present invention, as described above, contains a rare-earth element in an amount of 0.05 to 5 atomic % (the remainder is preferably Al and inevitable impurities). By setting the amount of the rare-earth element contained to the above lower limit or higher, heat resistance effects can be effectively produced, while in contrast, by setting the amount to the above upper limit or lower, the lower limit of the glossiness defined in the present invention can be ensured. That is, as shown in Examples described later, the glossiness of the aluminum alloy film has a close relationship with the amount of the rare-earth element contained, and when the aluminum alloy film is produced under the same conditions, as the amount of the rare-earth element contained increases, the glossiness of the aluminum alloy film tends to increase, but when the amount of the rare-earth element contained is too high, the new problem of etching residues occurs, which impairs the tone. Therefore, its upper limit is defined to be 5 atomic %. If the amount is within the above range, the electrical resistivity of the wiring can also be suppressed to a low level.

An example of the rare-earth element used in the present invention is the element group including lanthanoid elements (the 15 elements from atomic number 57 La to atomic number 71 Lu in the periodic table), with Sc (scandium) and Y (yttrium) added thereto. In the present invention, these elements may be used singly or in combination of two or more kinds, and the amount of the above rare-earth element contained is a sole amount when contained singly, and is the total amount when contained in combination of two or more kinds. A preferable rare-earth element is one or more element selected from the group consisting of Nd, Gd, La, Y, Ce, Pr and Dy.

In the present invention, a laminate in which refractory metal films are laminated above and below the above-mentioned aluminum alloy film is used as a wiring material. As described above, the refractory metal films are widely used as underlayers of the aluminum alloy film and the like to prevent oxidation of Al, and Mo, Ti, Cr, W and alloys of these may be used in the present invention. The compositions of the refractory metal films disposed above and below the aluminum alloy film may be the same or different from each other.

A preferable thickness of the above aluminum alloy film is about 150 to 600 nm, while a preferable thickness of the refractory metal film is about 30 to 100 nm.

In the present invention, in order to obtain an aluminum alloy film whose hardness and triple junction density are appropriately controlled, it is preferable to use an aluminum alloy film containing the predetermined rare-earth element, as well as to heat-treatment (anneal) the aluminum alloy film after the film formation within the range from room temperature to 230° C. In the production process of the touch panel, the touch panel is often subjected to a thermal hysteresis generally from room temperature to about 250° C., while when the annealing temperature is increased, because of the deposition of the rare-earth element and the grain growth of the Al alloy, the hardness and triple junction density are lowered. Specifically, depending on the amount of rare-earth element added, an appropriate annealing temperature may be set, but it is more preferably 150 to 230° C.

Further in the present invention, from the perspective of achieving fine lines and uniformity of the alloy components in the film, and facilitating controlling the amount of the element added, it is preferable to form the aluminum alloy film by the sputtering method. In the sputtering method, it is preferable to control the film formation temperature during sputtering to about 180° C. or lower, and the Ar gas pressure to about 3mTorr or lower. The higher the substrate temperature and film formation temperature, the more alike the quality of the film formed to bulk products, whereby a dense film is likely to be formed, and the hardness of the film tends to increase. Moreover, the density of the film tends to be reduced as the higher the Ar gas pressure is increased, and the hardness of the film tends to be lowered. Such adjustment of the film formation conditions is also preferable from the perspective of preventing the structure of the film from being sparse and thus promoting corrosion.

In the present invention, to obtain an aluminum alloy film in which the Young's modulus and maximum grain size are appropriately controlled, it is preferable to use an aluminum alloy film containing the predetermined rare-earth element, as well as to appropriately control the conditions during sputtering. That is, in the present invention, from the perspective of achieving fine lines and uniformity of the alloy components in the film, and easily controlling the amounts of elements added, it is recommended to form the aluminum alloy film by the sputtering method. It is preferable to control the film formation temperature during sputtering to about 230° C. or lower, and the Ar gas pressure to about 20 mTorr or lower. It is also preferable to control the substrate temperature during sputtering to about 180° C. or lower. The higher the substrate temperature and the film formation temperature, the more alike the quality of the film formed to bulk products, whereby a dense film is likely to be formed, and the Young's modulus of the film tends to increase. Moreover, the higher the Ar gas pressure is increased, the density of the film tends to be reduced, and the Young's modulus of the film tends to be reduced. Such adjustment of the film formation conditions is also preferable from the perspective of preventing the structure of the film from being sparse and thus promoting corrosion.

It should be noted that it is preferable to anneal the aluminum alloy film after being formed by the sputtering method as mentioned above (anneal) within the range from room temperature to 230° C. In the production process of the touch panel, the touch panel is often subjected to a thermal hysteresis generally from room temperature to about 250° C., while when the annealing temperature is increased, because of the deposition of the rare-earth element and the grain growth of the Al alloy, the Young's modulus and maximum grain size are lowered. Specifically, an appropriate annealing temperature may be set depending on the amount of the rare-earth element added, and the temperature is more preferably 150 to 230° C.

In the present invention, to obtain an aluminum alloy film whose glossiness is appropriately controlled, it is preferable to use an aluminum alloy film containing the predetermined rare-earth element, as well as to appropriately control the conditions during sputtering. That is, in the present invention, from the perspective of achieving fine lines and uniformity of the alloy components in the film, and easily controlling the amounts of elements added, it is recommended to form the aluminum alloy film by the sputtering method, it is preferable to control the film formation temperature during sputtering to about 250° C. or lower, and the Ar gas pressure to about 15 mTorr or lower. It is also preferable to control the substrate temperature during sputtering to about 250° C. or lower. The higher the substrate temperature and the film formation temperature, the more easier for sputter particles to move on the surface of the substrate, which leads to formation of coarse crystal grain particles, resulting in lowered glossiness. Moreover, when the Ar gas pressure is high, the frequency of the collision of sputter particles and the Ar gas pressure is increased, and therefore the energy of the sputter particles when they arrive at the substrate is lowered, and the density of crystal grains is reduced, resulting in lowered glossiness.

The glossiness of the aluminum alloy film formed (immediately after) under the preferable sputtering conditions mentioned above is as high as 800% or higher, and such high glossiness is maintained as it is, regardless the conditions of the heat treatment (annealing) performed thereafter. This point is largely different from the reflectance, which is greatly affected by the influence of the state (the size and density of crystal grains) of the aluminum alloy film after the heat treatment. In the production process of the touch panel, the touch panel is often subjected to a thermal hysteresis generally from room temperature to about 250° C., but even if the annealing temperature is above the above-mentioned range and the heat treatment is performed at, for example, 300° C., the glossiness of the aluminum alloy film of after the heat treatment is kept at a high level of 800% or higher (refer to Examples described later). However, considering the heat resistance of the resin, a preferable heat treatment temperature is about 150 to 230° C.

In the present invention, the greatest feature lies in that the glossiness of the aluminum alloy film used for the wiring connected to the transparent conductive film is defined. Other constitutions are not particularly limited, and known constitutions normally used in the field of the touch panel sensor can be employed.

For example, the resistance film type touch panel sensor can be manufactured in the following way. That is, after forming the transparent conductive film over the substrate, the resist application, exposure to light, development, and etching are performed on the substrate in that order. Then, the high-melting point metal film, the aluminum alloy film, and the high-melting point metal film are formed in that order, and the resist application, exposure to light, development, and etching are further performed to form the wiring. Then, the upper electrode can be formed by forming an insulating film or the like so as to cover the wiring. The transparent conductive film is formed over the substrate, and the same photolithography as that for formation of the upper electrode is performed. Then, the lower electrode can be formed by forming the wiring made of the high-melting point metal film, the aluminum alloy film, and the high-melting point metal film, forming an insulating film so as to cover the wiring, and forming a micro dot spacer or the like, in the same way as that of the upper electrode. Thereafter, the above-mentioned upper electrode, lower electrode, and a tail part separately formed are bonded together thereby to manufacture the touch panel sensor.

The transparent conductive film in use is not limited to a specific one, but can be made of indium tin oxide (ITO) or indium zinc oxide (IZO) by way of representative example. The substrate (transparent substrate) in use can be a generally-used one, such as glass, a polycarbonate-based one, or polyamide-based one. For example, glass can be used as the substrate of the lower electrode serving as a fixed electrode, and a polycarbonate-based film or the like can be used as the substrate of the upper electrode which is required to have plasticity.

The touch panel sensor of the invention can be used as a capacitance type or an ultrasonic surface elastic wave type touch panel sensor, in addition to the resistance film type one.

### EXAMPLES

### Example 1

An alkaline-free glass substrate (of 0.7 mm in thickness and 4 inches in diameter) was prepared as a substrate. Each aluminum alloy film having different types and amounts (unit: atomic %, with the remainder being Al and inevitably impurities) of rare-earth elements as shown in Table 1 (each having a thickness of about 500 nm) was deposited on the surface of the substrate by a DC magnetron sputtering method. Once the atmosphere in a chamber was set at an ultimate pressure of 3×10⁻⁶ Torr before deposition, the deposition was performed using a disk-like target made of the same composition as that of each aluminum alloy film and having a diameter of 4 inches on the following conditions. Subsequently, the Al alloys after the film formation were subjected to a heat treatment for 30 minutes at various annealing temperatures described in Table 1 in a nitrogen atmosphere. In Table 1, “⁻” means no heating (that is, room temperature). The composition of the aluminum alloy film formed was identified by an inductively coupled plasma (ICP) mass spectrometry.

### (Sputtering Conditions)

Ar Gas Pressure: 2 mTorr
Ar Gas Flow Rate: 30 sccm
Sputtering Power: 260 W
Substrate Temperature: room temperature

The film hardness measurement was performed by the nano indenter using the aluminum alloy film obtained as described above. In this measurement, continuous stiffness measurement was performed using an XP chip of each aluminum alloy film by a Nano Indenter XP (software for analysis: Test Works 4) manufactured by MTS Co. Ltd. An average of measured results of 15 points of each aluminum alloy film was determined under the following conditions: press depth of 300 nm, excited vibrational frequency of 45 Hz, and amplitude of 2 nm.

Furthermore, the aluminum alloy films obtained in the manner described above were observed with a TEM at 150,000 magnification, and the density of the Al alloy (triple junction density) existing at a grain boundary triple junction observed in a measurement field of view (a field of view sizing 1.2 μm×1.6 μm) was measured. The measurement was performed in three fields of view in total, and its average value was determined as the triple junction density of the Al alloy.

Samples in which pure Al films were formed in place of the aluminum alloy films were also measured for their hardness and triple junction density in a manner similar to that described above.

These results are also shown in Table 1. In Table 1, “E+07” means 10⁷. For example, the expression “9.0E+07” at No.1 in Table 1 means 9.0×10⁷.

TABLE 1

| | | Annealing | | |
|---|---|---|---|---|
| | | temperature | Triple joint density | |
| No. | Composition | (° C.) | (count/mm²) | Hardness (GPa) |
| 1 | pure-Al | — | 9.0E+07 | 0.925 |
| 2 | pure-Al | 150 | 5.9E+07 | 0.919 |
| 3 | pure-Al | 250 | 5.6E+07 | 0.917 |
| 4 | pure-Al | 300 | 2.9E+07 | 0.902 |
| 5 | Al—0.05Nd | — | 2.5E+08 | 2.374 |
| 6 | Al—0.05Nd | 150 | 2.4E+08 | 2.298 |
| 7 | Al—0.05Nd | 200 | 2.4E+08 | 2.141 |
| 8 | Al—0.05Nd | 250 | 1.2E+08 | 1.077 |
| 9 | Al—0.2Nd | — | 3.2E+08 | 2.908 |
| 10 | Al—0.2Nd | 150 | 2.6E+08 | 2.617 |
| 11 | Al—0.2Nd | 200 | 2.5E+08 | 2.495 |
| 12 | Al—0.2Nd | 250 | 1.2E+08 | 1.157 |
| 13 | Al—0.6Nd | — | 3.6E+08 | 3.202 |
| 14 | Al—0.6Nd | 150 | 3.0E+08 | 3.111 |
| 15 | Al—0.6Nd | 200 | 2.8E+08 | 2.716 |
| 16 | Al—0.6Nd | 230 | 2.1E+08 | 2.117 |
| 17 | Al—0.6Nd | 250 | 1.3E+08 | 1.143 |
| 18 | Al—0.6Nd | 300 | 5.0E+07 | 1.110 |
| 19 | Al—5.0Nd | — | 1.4E+09 | 14.740 |
| 20 | Al—5.0Nd | 150 | 8.9E+08 | 9.218 |
| 21 | Al—5.0Nd | 200 | 5.7E+08 | 5.316 |
| 22 | Al—5.0Nd | 250 | 2.1E+08 | 1.794 |
| 23 | Al—0.2Gd | — | 3.2E+08 | 3.071 |
| 24 | Al—0.2Gd | 150 | 2.7E+08 | 2.724 |
| 25 | Al—0.2Gd | 200 | 2.5E+08 | 2.445 |
| 27 | Al—0.2La | — | 3.3E+08 | 2.994 |
| 28 | Al—0.2La | 150 | 2.6E+08 | 2.589 |
| 29 | Al—0.2La | 200 | 2.4E+08 | 2.375 |
| 30 | Al—0.2Y | — | 3.1E+08 | 2.894 |
| 31 | Al—0.2Y | 150 | 2.5E+08 | 2.609 |
| 32 | Al—0.2Y | 200 | 2.4E+08 | 2.418 |
| 33 | Al—0.2Ce | — | 3.2E+08 | 3.002 |
| 34 | Al—0.2Ce | 150 | 2.7E+08 | 2.644 |
| 35 | Al—0.2Ce | 200 | 2.5E+08 | 2.478 |
| 36 | Al—0.2Pr | — | 3.2E+08 | 2.951 |
| 37 | Al—0.2Pr | 150 | 2.6E+08 | 2.668 |
| 38 | Al—0.2Pr | 200 | 2.4E+08 | 2.429 |
| 39 | Al—0.2Dy | — | 3.1E+08 | 2.908 |
| 40 | Al—0.2Dy | 150 | 2.5E+08 | 2.597 |
| 41 | Al—0.2Dy | 200 | 2.4E+08 | 2.422 |

In Table 1, Nos. 5 to 22 are all examples of the aluminum alloy films containing Nd as a rare-earth element. It can be seen that when the annealing temperatures are the same, the hardness and triple junction density tend to increase as the amount of Nd increases [for example, when the annealing temperature is room temperature (−), refer to Nos.5, 9, 13, and 19], and it is effective to set the upper limit of the amount of Nd to 1 atomic % to control the hardness and triple junction density to fall within the predetermined ranges. It can also be seen that even when the amounts of Nd are the same, if the annealing temperature is raised beyond the preferable range of the present invention, the hardness and triple junction density tend to decrease [for example, when the annealing temperature is 250° C., refer to Nos.8, 12, 17, and 22], and it is effective to control the upper limit of the annealing temperature to 230° C. to control the hardness and triple junction density to fall within the predetermined ranges.

In Table 1, Nos. 23 to 41 are examples using an aluminum alloy film containing a rare-earth element other than Nd. These examples all contained the rare-earth element in the amount defined in the present invention, and were prepared with the annealing temperature controlled to fall within the preferable range of the present invention, and therefore their hardness and triple junction density were controlled to fall within the ranges of the present invention. Moreover, it was experimentally confirmed that even when the above rare-earth element other than Nd was used, experiment results similar to those for Nd mentioned above were found (not shown in Table 1).

It can be greatly expected from these results that using the Al-rare-earth element alloy film of the present invention provides a highly reliable touch panel sensor which has excellent durability in the vertical direction, and hardly causes disconnection or an increase in electrical resistivity with the elapse of time.

In contrast, Nos. 1 to 4 are examples of pure Al containing no rare-earth element. They could not be controlled to have the hardness and triple junction density defined in the present invention, however the annealing temperature was controlled.

### Example 2

Thin-film samples having compositions shown in Table 2 were prepared in a manner similar to that in Example 1. Using the obtained aluminum alloy films, hardness tests of films were performed by a nano indentor, and their Young's moduli were measured. In this measurement, continuous stiffness measurement was performed using an XP chip of each aluminum alloy film by a Nano Indenter G200 (software for analysis: Test Works 4) manufactured by Agilent Technologies, Ltd. An average of measured results of 15 points of each aluminum alloy film was determined, with the press depth of 500 nm.

Furthermore, the aluminum alloy films obtained in the manner described above were observed with a TEM at 150,000 magnification, the grain size (unidirectional tangential diameter, Feret diameter) of crystal grains observed in a measurement field of view (a field of view sizing 1.2 μm×1.6 μm) was measured. The measurement was performed in three fields of view in total, and the maximum value in three fields of view was determined to be the maximum grain size.

Samples in which pure Al films were formed in place of the aluminum alloy films were also measured for Young's moduli and maximum grain size in a manner similar to that described above.

These results are also shown in Table 2.

TABLE 2

| | | | Young's | |
|---|---|---|---|---|
| | | Annealing | modulus | Maximum grain |
| No. | Composition | temperature (° C.) | (GPa) | size (nm) |
| 101 | pure-Al | — | 71 | 412 |
| 102 | pure-Al | 150 | 73 | 593 |
| 103 | pure-Al | 250 | 71 | 715 |
| 104 | pure-Al | 300 | 71 | 1066 |
| 105 | Al—0.05Nd | — | 86 | 161 |
| 106 | Al—0.05Nd | 150 | 85 | 170 |
| 107 | Al—0.05Nd | 200 | 84 | 179 |
| 108 | Al—0.05Nd | 250 | 73 | 210 |
| 109 | Al—0.2Nd | — | 91 | 158 |
| 110 | Al—0.2Nd | 150 | 88 | 165 |
| 111 | Al—0.2Nd | 200 | 87 | 167 |
| 112 | Al—0.2Nd | 250 | 74 | 221 |
| 113 | Al—0.6Nd | — | 95 | 140 |
| 114 | Al—0.6Nd | 150 | 94 | 142 |
| 115 | Al—0.6Nd | 200 | 89 | 148 |
| 116 | Al—0.6Nd | 230 | 83 | 188 |
| 117 | Al—0.6Nd | 250 | 73 | 213 |
| 118 | Al—0.6Nd | 300 | 72 | 427 |
| 119 | Al—5.0Nd | — | 197 | 142 |
| 120 | Al—5.0Nd | 150 | 139 | 143 |
| 121 | Al—5.0Nd | 200 | 110 | 149 |
| 122 | Al—5.0Nd | 250 | 80 | 201 |
| 123 | Al—0.2Gd | — | 93 | 139 |
| 124 | Al—0.2Gd | 150 | 90 | 144 |
| 125 | Al—0.2Gd | 200 | 87 | 145 |
| 126 | Al—0.2La | — | 92 | 148 |
| 127 | Al—0.2La | 150 | 88 | 147 |
| 128 | Al—0.2La | 200 | 86 | 159 |
| 129 | Al—0.2Y | — | 91 | 146 |
| 130 | Al—0.2Y | 150 | 88 | 149 |
| 131 | Al—0.2Y | 200 | 86 | 163 |
| 132 | Al—0.2Ce | — | 92 | 150 |
| 133 | Al—0.2Ce | 150 | 89 | 147 |
| 134 | Al—0.2Ce | 200 | 87 | 162 |
| 135 | Al—0.2Pr | — | 92 | 144 |
| 136 | Al—0.2Pr | 150 | 89 | 148 |
| 137 | Al—0.2Pr | 200 | 87 | 158 |
| 138 | Al—0.2Dy | — | 91 | 148 |
| 139 | Al—0.2Dy | 150 | 88 | 148 |
| 140 | Al—0.2Dy | 200 | 87 | 159 |

In Table 2, Nos. 105 to 122 are all examples of the aluminum alloy films containing Nd as a rare-earth element. When the sputtering conditions and annealing temperatures are all the same, the Young's moduli tend to increase as the amount of Nd increases [for example, when the annealing temperature is room temperature (−), refer to Nos.105, 109, 113, and 119], while the maximum grain sizes tend to slightly decrease. Even when the amounts of Nd and sputtering conditions are the same, if the annealing temperature is raised beyond the preferable range of the present invention, the Young's moduli decrease and the maximum grain sizes increase [for example, refer to Nos.117 and 118]. It can be therefore seen that it is effective to control the upper limit of the annealing temperature to 230° C. to control the Young's modulus and maximum grain size to fall within the predetermined ranges.

In Table 2, Nos. 123 to 140 are examples using an aluminum alloy film containing a rare-earth element other than Nd. These examples all contained the rare-earth element in the amount defined in the present invention, and were prepared with the sputtering conditions and annealing temperatures controlled to fall within the preferable range of the present invention, and therefore their Young's moduli and maximum grain sizes were controlled to fall within the ranges of the present invention. Moreover, it was experimentally confirmed that even when the above rare-earth element other than Nd was used, experiment results similar to those for Nd mentioned above were found (not shown in Table 2).

It can be greatly expected from these results that using the Al-rare-earth element alloy film of the present invention provides a highly reliable touch panel sensor which has excellent durability in the lateral direction, and hardly causes disconnection or an increase in electrical resistivity with the elapse of time.

In contrast, Nos. 101 to 103 are examples of pure Al containing no rare-earth element. They could not be controlled to have the Young's modulus and maximum grain size defined in the present invention, regardless of the annealing temperature.

### Example 3

Thin-film samples having compositions shown in Table 3 were prepared in a manner similar to that in Example 1. Using the obtained aluminum alloy films, their 60° relative-specular glossiness was measured in accordance with JIS K7105-1981. The glossiness was represented as a value (%) when the glossiness of a glass surface with an index of refraction of 1.567 was 100.

Etching residues were evaluated using the above-mentioned aluminium alloy films. Described in detail, an aluminum alloy film was immersed into a mixed acid etching solution (phosphoric acid: nitric acid: acetic acid:water=b 70:2:10:18) heated to 40° C. Etching was performed for a period of time (over-etching time) which is equivalent to etching completion time +50% time. The glass surface after the etching was observed with an optical microscope (magnification: 1000 times) and with a SEM (magnification: 30,000 times). Samples with which no etching residues was found in both observations were evaluated as A, those with which etching residues were found only in the SEM observation were evaluated as B, those with which etching residues were found not only in the SEM observation but also in the observation with the optical microscope were evaluated as C. In this Example, A or B are determined to have good etching characteristics.

Samples in which pure Al films were formed in place of the aluminum alloy films were also measured for glossiness and etching residues in a manner similar to that described above.

These results are also shown in Table 3. Table 3 shows the results of the glossiness after the heat treatment (annealing). It was confirmed that these values were hardly changed from the glossiness immediately after the film formation (before annealing).

TABLE 3

| | | Annealing | | Maximum | |
|---|---|---|---|---|---|
| | | temperature | Glossiness | grain | Etching |
| No. | Composition | (° C.) | (%) | size (nm) | residue |
| 201 | pure-Al | — | 775 | 412 | A |
| 202 | pure-Al | 150 | 759 | 593 | A |
| 203 | pure-Al | 300 | 777 | 1066 | A |
| 204 | Al—0.02Nd | — | 786 | 273 | A |
| 205 | Al—0.05Nd | — | 802 | 161 | A |
| 206 | Al—0.2Nd | — | 810 | 158 | A |
| 207 | Al—0.6Nd | — | 819 | 140 | A |
| 208 | Al—0.6Nd | 150 | 821 | 142 | A |
| 209 | Al—0.6Nd | 300 | 817 | 427 | A |
| 210 | Al—3.0Nd | — | 820 | 141 | A |
| 211 | Al—5.0Nd | — | 825 | 142 | B |
| 212 | Al—0.2Gd | — | 812 | 139 | A |
| 213 | Al—0.2La | — | 807 | 148 | A |
| 214 | Al—0.2Y | — | 809 | 146 | A |
| 215 | Al—0.2Ce | — | 810 | 150 | A |
| 216 | Al—0.2Pr | — | 813 | 144 | A |
| 217 | Al—0.2Dy | — | 809 | 148 | A |

In Table 3, Nos. 204 to 211 are all examples of the aluminum alloy films containing Nd as a rare-earth element. It can be seen that when the sputtering conditions and annealing temperatures are all the same, the glossiness tends to increase as the amount of Nd increases [for example, when the annealing temperature is room temperature (−), refer to Nos.204, 205, 206, 207, 210, and 211]. Moreover, etching residues are observed as the amount of Nd increases, but the samples were determined to fall within the acceptable range when the upper limit (5 atomic %) was within the range defined in the present invention.

In Table 3, Nos. 212 to 217 are examples using an aluminum alloy film containing a rare-earth element other than Nd. These examples all contained the rare-earth element in the amount defined in the present invention, and were prepared with the sputtering conditions controlled to fall within the preferable range of the present invention, and therefore the glossiness was controlled to fall within the ranges of the present invention. Moreover, it was experimentally confirmed that even when the above rare-earth element other than Nd was used, experiment results similar to those for Nd mentioned above were found (not shown in Table 3).

It can be greatly expected from these results that using the Al-rare-earth element alloy film of the present invention provides a touch panel sensor with high glossiness.

In contrast, Nos. 201 to 203 are examples of pure Al containing no rare-earth element. Although the sputtering conditions were controlled to fall within the preferable range of the present invention, their glossiness could not be controlled to fall within the range of the glossiness defined in the present invention.

The present invention has been explained in detail or with reference to the specific embodiments. However, it will be understood to those skilled in the art that various changes and modifications can be made without departing from the spirit and scope of the invention.

The Present application claims priority from Japanese Patent Application No. 2010-268687 filed on Dec. 1, 2010, Japanese Patent Application No. 2010-268688 filed on Dec. 1, 2010, and Japanese Patent Application No. 2010-268689 filed on Dec. 1, 2010, the content of which is hereby incorporated by reference into this application.

### INDUSTRIAL APPLICABILITY

According to the present invention, in a touch panel sensor using a wiring material in which refractory metal films are disposed above and below an aluminum alloy film containing a rare-earth element as a wiring for a touch panel sensor, the hardness and grain boundary triple junction density of the above aluminum alloy film are appropriately controlled, and therefore a highly reliable touch panel sensor which has excellent durability, in particular, in the vertical direction such as push load, and hardly causes disconnection or an increase in electrical resistance with the elapse of time could be provided. The present invention is effective as various kinds of touch panels, and is suitably used for a contact-type touch panel sensor operated by pressing portions displayed on the screen, for example, automatic teller machines installed in financial institutions such as banks, and automatic vending machines at stations and restaurants. Moreover, since the Young's modulus and the maximum value of the unidirectional tangential diameter of crystal grains (Feret diameter) of the above aluminum alloy film are appropriately controlled, a touch panel with high reliability which has excellent durability in the lateral direction, and hardly causes disconnection or an increase in electrical resistivity with the elapse of time could be provided. The touch panel of the present invention, is suitably used for a capacitative touch panel sensor, for example, a portable game console and a tablet type computer, which is operated by sliding a finger or the like on a screen thereof in many directions. Furthermore, use of an aluminum alloy film having excellent glossiness allows providing a touch panel sensor with excellent color expression.

1. A touch panel sensor, comprising:
a substrate;
a transparent conductive film comprising indium tin oxide ITO or indium zinc oxide IZO; and
a wiring connected with the transparent conductive film and comprising, in an order from the substrate;
a first refractory metal film,
an aluminum alloy film comprising at least one rare earth element selected from the group consisting of Nd, Gd, La, Y, Ce, Pr, and Dy in an amount of 0.05 to 5 atomic % and
a second refractory metal film,
wherein the first and the second refractory metal film comprises at least one metal selected from the group consisting of Mo, Ti, Cr, and W.

2-3. (canceled)

4. The touch panel sensor according to claim 1, wherein the aluminum alloy film comprises the at least one rare-earth element in an amount of 0.05 to 1 atomic %; has a hardness of from 2 to 3.5 GPa; and has a density of grain boundary triple junction present in an Al alloy structure of 2×10⁸/mm² or higher.

5. The touch panel sensor according to claim 1, wherein the aluminum alloy film has a Young's modulus of from 80 to 200 GPa and a maximum value of a unidirectional tangential diameter of crystal grains of from 100 to 350 nm.

6. The touch panel sensor according to claim 1, wherein the aluminum alloy film has a glossiness of 800% or higher.
